(19) United States
(12) Patent Application Publication
(10) Pub. No.: US 2023/0002640 A1
(43) Pub. Date: Jan. 5, 2023

(54) COMPOSITION FOR CHEMICAL MECHANICAL POLISHING AND METHOD FOR POLISHING

(71) Applicant: JSR CORPORATION, Tokyo (JP)

(72) Inventors: Kouhei Nishimura, Tokyo (JP); Yuuya Yamada, Tokyo (JP); Shuuhei Nakamura, Tokyo (JP); Pengyu Wang, Tokyo (JP)

(73) Assignee: JSR CORPORATION, Tokyo (JP)

(21) Appl. No.: 17/781,712

(22) PCT Filed: Nov. 17, 2020
(86) PCT No.: PCT/JP2020/042779

§ 371 Date: Jun. 2, 2022

(30) Foreign Application Priority Data
Dec. 12, 2019 (JP) 2019-224280

(51) Int. Cl. C09G 1/02; C09K 3/14; H01L 21/321; H01L 21/3105

(52) U.S. Cl. CPC C09G 1/02; C09K 3/1409; H01L 21/3212; H01L 21/31053

(57) ABSTRACT

Provided are a composition for chemical mechanical polishing and a method for polishing allowing a tungsten film- or silicon nitride film-containing semiconductor substrate to be polished at a high speed, while also enabling a reduction in the occurrence of a surface defect in the polished face after polishing. A composition for chemical mechanical polishing according to the present invention comprises (A) abrasive grains containing titanium nitride and (B) a liquid medium, wherein the absolute value of the zeta-potential of said (A) component in the composition for chemical mechanical polishing is 8 mV or higher.

### TECHNICAL FIELD

The present invention relates to a composition for chemical mechanical polishing and a polishing method using the same.

### BACKGROUND ART

Generally, a chemical mechanical polishing (hereinafter referred to as “CMP”) method is used in a semiconductor manufacturing process, specifically, in flattening of an interlayer insulating film, formation of a metal plug, and formation of an embedded wiring (damascene wiring) in a multi-layer wiring forming process. In such a semiconductor manufacturing process, materials such as tungsten and silicon nitride are used, and not only are these materials required to be polished at a high speed but also polishing performance in which high flatness and fewer polishing defects are balanced is required.

In order to realize such well-balanced polishing characteristics, for example, a polishing composition (slurry) for polishing a tungsten film or a silicon nitride film has been studied (for example, refer to Patent Literature 1 and 2).

### CITATION LIST

### Patent Literature

Patent Literature 1: Japanese Patent Laid-Open No. 2017-515298

Patent Literature 2: PCT International Publication No. WO 2014/103725

### SUMMARY OF INVENTION

### Technical Problem

When a polishing composition containing abrasive grains having high hardness is used, it is possible to improve the polishing rate of the tungsten film or the silicon nitride film. However, CMP using a polishing composition containing abrasive grains having high hardness has a problem of polishing scratches being likely to occur on the polished surface after polishing. In addition, CMP using a polishing composition containing abrasive grains having high hardness has a problem in which surface defects called dishing in which a conductor metal part is scraped into a dish shape are likely to occur on the polished surface on which a conductor metal and an insulating film coexist. Accordingly, there is a demand for a composition for chemical mechanical polishing and a polishing method in which it is possible to reduce the occurrence of surface defects on a polished surface after polishing while polishing a semiconductor substrate containing a tungsten film or a silicon nitride film at a high speed.

### Solution to Problem

One aspect of a composition for chemical mechanical polishing according to the present invention includes

(A) abrasive grains containing titanium oxide; and

(B) a liquid medium,

wherein an absolute value of a zeta potential of the component (A) in the composition for chemical mechanical polishing is 8 mV or higher.

In one aspect of the composition for chemical mechanical polishing, the component (A) may further contain an aluminum compound or a silicon compound.

In any of the above aspects of the composition for chemical mechanical polishing, the component (A) may have a functional group represented by the following General Formula (1):

—SO₃⁻M⁺ (1)

(M⁺ represents a monovalent cation).

In any of the above aspects of the composition for chemical mechanical polishing, the component (A) may be abrasive grains having a surface to which the functional group represented by General Formula (1) is fixed via a covalent bond and containing titanium oxide.

In any of the above aspects of the composition for chemical mechanical polishing, the zeta potential of the component (A) in the composition for chemical mechanical polishing may be −10 mV or lower.

In any of the above aspects of the composition for chemical mechanical polishing, the component (A) may have a functional group represented by the following General Formula (2):

—COO⁻M⁺ (2)

(M⁺ represents a monovalent cation).

In any of the above aspects of the composition for chemical mechanical polishing, the component (A) may be abrasive grains having a surface to which the functional group represented by General Formula (2) is fixed via a covalent bond and containing titanium oxide.

In any of the above aspects of the composition for chemical mechanical polishing, the zeta potential of the component (A) in the composition for chemical mechanical polishing may be −10 mV or lower.

In any of the above aspects of the composition for chemical mechanical polishing, the component (A) may have a functional group represented by the following General Formula (3) or the following General Formula (4):

—NR¹R² (3)

—N⁺R¹R²R³M⁻ (4)

(in Formulae (3) and (4), R¹, R² and R³ each independently represent a hydrogen atom or a substituted or unsubstituted hydrocarbon group; and M⁻ represents an anion).

In any of the above aspects of the composition for chemical mechanical polishing, the component (A) may be abrasive grains having a surface to which the functional group represented by General Formula (3) or the General Formula (4) is fixed via a covalent bond and containing titanium oxide.

In any of the above aspects of the composition for chemical mechanical polishing, the zeta potential of the component (A) in the composition for chemical mechanical polishing may be +10 mV or higher.

In any of the above aspects of the composition for chemical mechanical polishing, the pH may be 1 or more and 6 or less.

In any of the above aspects of the composition for chemical mechanical polishing, the content of the component (A) with respect to a total mass of the composition for chemical mechanical polishing may be 0.1 mass % or more and 20 mass % or less.

Any of the aspects of the composition for chemical mechanical polishing may further include (C) at least one selected from the group consisting of organic acids and salts thereof.

One aspect of a polishing method according to the present invention includes a process in which a semiconductor substrate is polished using the composition for chemical mechanical polishing according to any of the above aspects.

In one aspect of the polishing method, the semiconductor substrate may have a part containing at least one of a tungsten film and a silicon nitride film.

### Advantageous Effects of Invention

According to the composition for chemical mechanical polishing of the present invention, it is possible to polish a semiconductor substrate including a tungsten film or a silicon nitride film at a high speed and reduce the occurrence of surface defects on a polished surface after polishing. In addition, according to the polishing method of the present invention, when the composition for chemical mechanical polishing is used, a semiconductor substrate including a tungsten film or a silicon nitride film is polished at a high speed and a polished surface having few surface defects is obtained.

### BRIEF DESCRIPTION OF DRAWINGS

FIG. 1 is a cross-sectional view schematically showing a workpiece suitable for use in a polishing method according to the present embodiment.

FIG. 2 is a cross-sectional view schematically showing a workpiece when a first polishing process ends.

FIG. 3 is a cross-sectional view schematically showing a workpiece when a second polishing process ends.

FIG. 4 is a perspective view schematically showing a chemical mechanical polishing device.

### DESCRIPTION OF EMBODIMENTS

Preferable embodiments of the present invention will be described below in detail. Here, the present invention is not limited to the following embodiments, and includes various modified examples implemented in ranges without changing the spirit of the present invention.

In this specification, a numerical range described as “X to Y” is interpreted as a range including the numerical value X as a lower limit value and the numerical value Y as an upper limit value.

### 1. Composition for Chemical Mechanical Polishing

A composition for chemical mechanical polishing according to one embodiment of the present invention contains (A) abrasive grains containing titanium oxide (hereinafter referred to as a “component (A)”), and (B) a liquid medium (hereinafter referred to as a “component (B)”), and the absolute value of the zeta potential of the component (A) in the composition for chemical mechanical polishing is 8 mV or higher. Hereinafter, respective components contained in the composition for chemical mechanical polishing according to the present embodiment will be described in detail.

1.1. (A) Abrasive Grains Containing Titanium Oxide

A composition for chemical mechanical polishing according to the present embodiment contains (A) abrasive grains containing titanium oxide. The component (A) is not particularly limited as long as it is abrasive grains which contain titanium oxide and in which the absolute value of the zeta potential in the composition for chemical mechanical polishing is 8 mV or higher. Regarding titanium oxide contained in the component (A), any of a rutile type, an anatase type, an amorphous type, and a mixture thereof can be used.

The absolute value of the zeta potential of the component (A) in the composition for chemical mechanical polishing is 8 mV or higher, preferably 9 mV or higher, and more preferably 10 mV or higher. The absolute value of the zeta potential of the component (A) in the composition for chemical mechanical polishing is preferably 40 mV or lower. When the absolute value of the zeta potential of the component (A) in the composition for chemical mechanical polishing is within the above range, the dispersibility of abrasive grains in the composition for chemical mechanical polishing is improved due to an electrostatic repulsion force between abrasive grains. As a result, high-speed polishing can be performed while reducing the occurrence of polishing scratches and dishing.

The average particle size of the component (A) is preferably 10 nm or more and 300 nm or less, and more preferably 20 nm or more and 200 nm or less. When the average particle size of the component (A) is within the above range, a sufficient polishing rate can be obtained and in some cases, a composition for chemical mechanical polishing having excellent stability that does not cause precipitation or separation of particles can be obtained. Here, a specific surface area is measured by a BET method using, for example, a flow type specific surface area automatic measuring device (“micrometrics FlowSorb II 2300” commercially available from Shimadzu Corporation), and the average particle size of the component (A) can be calculated from the measured value.

The component (A) is abrasive grains containing titanium oxide as a main component, but other components may be contained. Examples of other components include an aluminum compound and a silicon compound. When the component (A) further contains an aluminum compound or a silicon compound, since the surface hardness of the component (A) can be reduced, it is possible to further reduce the occurrence of polishing scratches and dishing on the polished surface in some cases while polishing a semiconductor substrate including a tungsten film or a silicon nitride film at a high speed.

Examples of aluminum compounds include aluminum hydroxide, aluminum oxide (alumina), aluminum chloride, aluminum nitride, aluminum acetate, aluminum phosphate, aluminum sulfate, sodium aluminate, and potassium aluminate. On the other hand, examples of silicon compounds include silicon dioxide, silicon nitride, silicon carbide, silicate, silicone, and silicon resins.

The component (A) is preferably abrasive grains of which at least a portion of the surface is modified with a functional group. In a pH range of 1 or more and 6 or less, compared to abrasive grains of which the surface is not modified with a functional group, in abrasive grains of which at least a portion of the surface is modified with a functional group, the absolute value of the zeta potential is larger, and an electrostatic repulsion force between abrasive grains increases. As a result, the dispersibility of abrasive grains in the composition for chemical mechanical polishing is improved, and thus high-speed polishing can be performed while reducing the occurrence of polishing scratches and dishing.

In addition, titanium oxide particles easily react with water, oxygen, nitrogen and the like and tend to deteriorate over time. However, when the component (A) is abrasive grains of which at least a portion of the surface is modified with a functional group, the functional group can reduce the reactivity with respect to water, oxygen, nitrogen, and the like on the surface of the abrasive grains, and minimize deterioration.

Hereinafter, specific aspects of the component (A) will be described.

1.1.1. First Aspect

As a first aspect of the component (A), abrasive grains having a functional group represented by the following General Formula (1) and containing titanium oxide are exemplified.

—SO₃⁻M⁺ (1)

(M⁺ represents a monovalent cation).

In Formula (1), examples of monovalent cations represented by M⁺ include H⁺, Li⁺, Na⁺, K⁺, and NH₄⁺, but the present invention is not limited thereto. That is, in other words, the functional group represented by General Formula (1) may be “at least one functional group selected from the group consisting of a sulfo group and salts thereof.” Here, “a salt of a sulfo group” is a functional group in which a hydrogen ion contained in a sulfo group (—SO₃H) is replaced with a monovalent cation such as Li⁺, Na⁺, K⁺, or NH₄⁺. The component (A) according to the first aspect is abrasive grains having a surface to which the functional group represented by General Formula (1) is fixed via a covalent bond and containing titanium oxide, and does not include a component having a surface to which a compound having the functional group represented by General Formula (1) is physically or ionically adsorbed.

The component (A) according to the first aspect can be manufactured, for example, by applying the method described in Japanese Patent Laid-Open No. 2010-269985. Specifically, when titanium oxide and a mercapto group-containing silane coupling agent are sufficiently stirred in an acidic medium, the mercapto group-containing silane coupling agent is covalently bonded to the surface of the abrasive grains containing titanium oxide. Here, examples of mercapto group-containing silane coupling agents include 3-mercaptopropylmethyldimethoxysilane and 3-mercaptopropyltrimethoxysilane. Next, an appropriate amount of hydrogen peroxide is additionally added and left for a sufficient time, and thus it is possible to obtain abrasive grains having the functional group represented by General Formula (1) and containing titanium oxide.

The zeta potential of the component (A) according to the first aspect is a negative potential in the composition for chemical mechanical polishing, and the negative potential is preferably −10 mV or lower, and more preferably −20 mV or lower. When the zeta potential of the component (A) according to the first aspect is within the above range, an electrostatic repulsion force between abrasive grains can effectively prevent particles from aggregating and it is possible to selectively polish a substrate that has a positive charge during chemical mechanical polishing in some cases. Here, examples of zeta potential measuring devices include “ELSZ-1” (commercially available from Otsuka Electronics Co., Ltd.) and “Zetasizer nano zs” (commercially available from Malvern). The zeta potential of the component (A) according to the first aspect can be adjusted by appropriately increasing or decreasing an amount of the above mercapto group-containing silane coupling agent or the like added.

When the composition for chemical mechanical polishing according to the present embodiment contains the component (A) according to the first aspect, the lower limit value of the content of the component (A) according to the first aspect with respect to a total mass of 100 mass % of the composition for chemical mechanical polishing is preferably 0.1 mass %, and more preferably 0.5 mass %. The upper limit value of the content of the component (A) according to the first aspect with respect to a total mass of 100 mass % of the composition for chemical mechanical polishing is preferably 10 mass %, and more preferably 5 mass %. When the content of the component (A) according to the first aspect is within the above range, it is possible to polish a semiconductor substrate including a tungsten film or a silicon nitride film at a high speed and storage stability of the composition for chemical mechanical polishing can be improved in some cases.

1.1.2. Second Aspect

As a second aspect of the component (A), abrasive grains having the functional group represented by the following General Formula (2) and containing titanium oxide are exemplified.

—COO⁻M⁺ (2)

(M⁺ represents a monovalent cation).

In Formula (2), examples of monovalent cations represented by M⁺ include H⁺, Li⁺, Na⁺, K⁺, and NH₄⁺, but the present invention is not limited thereto. That is, in other words, the functional group represented by General Formula (2) may be “at least one functional group selected from the group consisting of a carboxyl group and salts thereof.” Here, “a salt of a carboxyl group” is a functional group in which a hydrogen ion contained in a carboxyl group (—COOH) is replaced with a monovalent cation such as Li⁺, Na⁺, K⁺, or NH₄⁺. The component (A) according to the second aspect is abrasive grains having a surface to which the functional group represented by General Formula (2) is fixed via a covalent bond and containing titanium oxide, and does not include a component having a surface to which a compound having the functional group represented by General Formula (2) is physically or ionically adsorbed.

The component (A) according to the second aspect can be manufactured, for example, by applying the method described in Japanese Patent Laid-Open No. 2010-105896. Alternatively, when titanium oxide and a carboxylic acid anhydride-containing silane coupling agent are sufficiently stirred in a basic medium composed of water, methanol, and ammonia, a carboxylic acid anhydride silane coupling agent is covalently bonded to the surface of the abrasive grains containing titanium oxide, and the modified acid anhydride is additionally hydrolyzed to cause a ring-opening reaction in the dicarboxylic acid, and thus it is possible to obtain abrasive grains having the functional group represented by General Formula (2) and containing titanium oxide. Here, examples of carboxylic acid anhydride-containing silane coupling agents include 3-(triethoxysilyl)propyl succinic anhydride.

The zeta potential of the component (A) according to the second aspect is a negative potential in the composition for chemical mechanical polishing, and the negative potential is preferably −10 mV or lower, and more preferably −12 mV or lower. When the zeta potential of the component (A) according to the second aspect is within the above range, an electrostatic repulsion force between abrasive grains can effectively prevent particles from aggregating, and it is possible to selectively polish a substrate that has a positive charge during chemical mechanical polishing in some cases. Here, regarding the zeta potential measuring device, the device described in the first aspect can be used. The zeta potential of the component (A) according to the second aspect can be adjusted by appropriately increasing or decreasing an amount of the above carboxylic acid anhydride-containing silane coupling agent or the like added.

When the composition for chemical mechanical polishing according to the present embodiment contains the component (A) according to the second aspect, the lower limit value of the content of the component (A) according to the second aspect with respect to a total mass of 100 mass % of the composition for chemical mechanical polishing is preferably 0.1 mass %, more preferably 0.3 mass %, and particularly preferably 0.5 mass %. The upper limit value of the content of the component (A) according to the second aspect with respect to a total mass of 100 mass % of the composition for chemical mechanical polishing is preferably 10 mass %, more preferably 8 mass %, and particularly preferably 5 mass %. When the content of the component (A) according to the second aspect is within the above range, it is possible to polish a semiconductor substrate including a tungsten film or a silicon nitride film at a high speed and storage stability of the composition for chemical mechanical polishing can be improved in some cases.

1.1.3. Third Aspect

As a third aspect of the component (A), abrasive grains having the functional group represented by the following General Formula (3) or the following General Formula (4) and containing titanium oxide are exemplified.

—NR¹R² (3)

—N⁺R¹R²R³M⁻ (4)

(in Formula (3) and Formula (4), R¹, R² and R³ each independently represent a hydrogen atom or a substituted or unsubstituted hydrocarbon group; and M⁻ represents an anion).

The functional group represented by General Formula (3) represents an amino group, and the functional group represented by General Formula (4) represents a salt of an amino group. Therefore, in other words, the functional group represented by General Formula (3) and the functional group represented by General Formula (4) collectively indicate “at least one functional group selected from the group consisting of an amino group and salts thereof.” The component (A) according to the third aspect is abrasive grains containing titanium oxide having a surface to which the functional group represented by General Formula (3) or General Formula (4) is fixed via a covalent bond and does not include a component having a surface to which a compound having the functional group represented by General Formula (3) or General Formula (4) is physically or ionically adsorbed.

In Formula (4), examples of anions represented by M⁻ include anions derived from an acidic compound in addition to anions such as OH⁻, F⁻, Cl⁻, Br⁻, I⁻, and CN⁻, but the present invention is not limited thereto.

In Formula (3) and Formula (4), R¹ to R³ each independently represent a hydrogen atom or a substituted or unsubstituted hydrocarbon group, but two or more of R¹ to R³ may be bonded to form a ring structure.

Hydrocarbon groups represented by R¹ to R³ may be any of aliphatic hydrocarbon groups, aromatic hydrocarbon groups, aromatic aliphatic hydrocarbon groups and alicyclic hydrocarbon groups. In addition, for aliphaticity, aliphatic hydrocarbon groups and aromatic aliphatic hydrocarbon groups may be saturated or unsaturated or may be linear or branched. Examples of these hydrocarbon groups include linear, branched, cyclic alkyl groups, alkenyl groups, aralkyl groups, and aryl groups.

Generally, the alkyl group is preferably a lower alkyl group having 1 to 6 carbon atoms and more preferably a lower alkyl group having 1 to 4 carbon atoms. Examples of such an alkyl group include a methyl group, ethyl group, n-propyl group, iso-propyl group, n-butyl group, iso-butyl group, sec-butyl group, tert-butyl group, n-pentyl group, iso-pentyl group, sec-pentyl group, tert-pentyl group, neopentyl group, n-hexyl group, iso-hexyl group, sec-hexyl group, tert-hexyl group, cyclopentyl group, and cyclohexyl group.

Generally, the alkenyl group is preferably a lower alkenyl group having 1 to 6 carbon atoms and more preferably a lower alkenyl group having 1 to 4 carbon atoms. Examples of such an alkenyl group include a vinyl group, n-propenyl group, iso-propenyl group, n-butenyl group, iso-butenyl group, sec-butenyl group, and tert-butenyl group.

Generally, an aralkyl group having 7 to 12 carbon atoms is preferable. Examples of such an aralkyl group include a benzyl group, phenethyl group, phenylpropyl group, phenylbutyl group, phenylhexyl group, methylbenzyl group, methylphenethyl group, and ethylbenzyl group.

Generally, an aryl group having 6 to 14 carbon atoms is preferable. Examples of such an aryl group include a phenyl group, o-tolyl group, m-tolyl group, p-tolyl group, 2,3-xylyl group, 2,4-xylyl group, 2,5-xylyl group, 2,6-xylyl group, 3,5-xylyl group, naphthyl group, and anthryl group.

The aromatic ring of the aryl group and the aralkyl group may have, for example, a lower alkyl group such as a methyl group and an ethyl group, a halogen atom, a nitro group, an amino group, a hydroxy group or the like as a substituent.

The component (A) according to the third aspect can be manufactured, for example, by applying the method described in Japanese Patent Laid-Open No. 2005-162533. Specifically, when titanium oxide and an amino group-containing silane coupling agent are sufficiently stirred in an acidic medium, the amino group-containing silane coupling agent can be covalently bonded to the surface of the abrasive grains containing titanium oxide for achievement. Here, examples of amino group-containing silane coupling agents include 3-aminopropyltrimethoxysilane and 3-aminopropyltriethoxysilane.

The zeta potential of the component (A) according to the third aspect is a positive potential in the composition for chemical mechanical polishing, and the positive potential is preferably +10 mV or higher and more preferably +15 mV or higher. When the zeta potential of the component (A) according to the third aspect is within the above range, an electrostatic repulsion force between abrasive grains can effectively prevent particles from aggregating, and it is possible to selectively polish a substrate that has a negative charge during chemical mechanical polishing in some cases. Here, regarding the zeta potential measuring device, the device described in the first aspect can be used. The zeta potential of the component (A) according to the third aspect can be adjusted by appropriately increasing or decreasing an amount of the above amino group-containing silane coupling agent or the like added.

When the composition for chemical mechanical polishing according to the present embodiment contains the component (A) according to the third aspect, the lower limit value of the content of the component (A) according to the third aspect with respect to a total mass of 100 mass % of the composition for chemical mechanical polishing is preferably 0.1 mass %, more preferably 0.5 mass %, and particularly preferably 1 mass %. The upper limit value of the content of the component (A) according to the third aspect with respect to a total mass of 100 mass % of the composition for chemical mechanical polishing is preferably 10 mass %, more preferably 8 mass %, and particularly preferably 5 mass %. When the content of the component (A) according to the third aspect is within the above range, it is possible to polish a semiconductor substrate including a tungsten film or a silicon nitride film at a high speed and storage stability of the composition for chemical mechanical polishing can be improved in some cases.

1.2. (B) Liquid Medium

The composition for chemical mechanical polishing according to the present embodiment contains (B) a liquid medium. Examples of the component (B) include water, a mixed medium containing water and an alcohol, and a mixed medium containing water and an organic solvent compatible with water. Among these, water or a mixed medium containing water and an alcohol is preferably used, and water is more preferably used. Water is not particularly limited, and pure water is preferable. Water may be added as the remainder of the constituent material of the composition for chemical mechanical polishing, and the content of water is not particularly limited.

1.3. (C) Organic Acids and Salts Thereof

The composition for chemical mechanical polishing according to the present embodiment preferably contains at least one selected from the group consisting of (C) an organic acid and a salt thereof (hereinafter referred to as a “component (C)”). When the component (C) is contained, it is possible to polish a semiconductor substrate including a tungsten film or a silicon nitride film at a higher speed in some cases.

Regarding the component (C), a compound having a carboxyl group or a compound having a sulfo group is preferable. Examples of compounds having a carboxyl group include stearic acid, lauric acid, oleic acid, myristic acid, alkenyl succinic acids, lactic acid, tartaric acid, fumaric acid, glycolic acid, phthalic acid, maleic acid, formic acid, acetic acid, oxalic acid, citric acid, malic acid, malonic acid, glutaric acid, succinic acid, benzoic acid, quinolphosphoric acid, quinaldic acid, amidosulfuric acid, propionic acid, and trifluoroacetic acid; amino acids such as glycine, alanine, aspartic acid, glutamic acid, lysine, arginine, tryptophan, dodecylaminoethylaminoethylglycine, aromatic amino acids, and heterocyclic amino acids; imino acids such as alkylimino dicarboxylic acids; and salts thereof. In addition, it may be a polymer compound having a carboxyl group, and may be, for example, a polyacrylic acid or a salt thereof. Examples of compounds having a sulfo group include alkylbenzene sulfonic acids such as dodecylbenzene sulfonic acid and p-toluenesulfonic acid; alkylnaphthalene sulfonic acids such as butylnaphthalene sulfonic acid; and α-olefin sulfonic acids such as tetradecene sulfonic acid. These compounds may be used alone or two or more thereof may be used in combination.

The lower limit value of the content of the component (C) with respect to a total mass of 100 mass % of the composition for chemical mechanical polishing is preferably 0.0001 mass %, and more preferably 0.01 mass %. The upper limit value of the content of the component (C) with respect to a total mass of 100 mass % of the composition for chemical mechanical polishing is preferably 10 mass %, and more preferably 5 mass %. When the content of the component (C) is within the above range, it is possible to polish a semiconductor substrate including a tungsten film or a silicon nitride film at a higher speed in some cases.

1.4. (D) Oxidant

The composition for chemical mechanical polishing according to the present embodiment preferably contains (D) an oxidant (hereinafter referred to as a “component (D)”). When the oxidant is contained, a polished surface of a semiconductor substrate including a tungsten film or a silicon nitride film is oxidized to promote a complex reaction with a polishing liquid component and thus a fragile modified layer can be formed on the polished surface so that there is an effect of ease of polishing.

Examples of the component (D) include ammonium persulfate, potassium persulfate, hydrogen peroxide, ferric nitrate, cerium diammonium nitrate, potassium hypochlorite, ozone, potassium periodate, and peracetic acid. Among these components (D), in consideration of oxidizing power and ease of handling, ammonium persulfate, potassium persulfate, and hydrogen peroxide are preferable, and hydrogen peroxide is more preferable. These components (D) may be used alone or two or more thereof may be used in combination.

The lower limit value of the content of the component (D) with respect to a total mass of 100 mass % of the composition for chemical mechanical polishing is preferably 0.05 mass %, and more preferably 0.1 mass %. The upper limit value of the content of the component (D) with respect to a total mass of 100 mass % of the composition for chemical mechanical polishing is preferably 5 mass %, and more preferably 4 mass %.

1.5. Other Components

The composition for chemical mechanical polishing according to the present embodiment may contain, as necessary, a nitrogen-containing heterocyclic compound, a surfactant, an inorganic acid and a salt thereof, a water-soluble polymer, a basic compound and the like, in addition to the above components.

<Nitrogen-Containing Heterocyclic Compound>

The nitrogen-containing heterocyclic compound is an organic compound containing at least one heterocyclic ring selected from among a five-membered ring complex and a complex six-membered ring, which has at least one nitrogen atom. Specific examples of heterocyclic rings include five-membered ring complexes having a pyrrole structure, an imidazole structure, a triazole structure or the like; and complex six-membered rings having a pyridine structure, a pyrimidine structure, a pyridazine structure, a pyrazine structure or the like. The heterocyclic ring may form a condensed ring. Specifically, an indole structure, an isoindole structure, a benzimidazole structure, a benzotriazole structure, a quinoline structure, an isoquinoline structure, a quinazoline structure, a cinnoline structure, a phthalazine structure, a quinoxaline structure, an acridine structure and the like may be exemplified. Among the heterocyclic ring compounds having such a structure, a heterocyclic ring compound having a pyridine structure, a quinoline structure, a benzimidazole structure, or a benzotriazole structure is preferable.

Specific examples of nitrogen-containing heterocyclic compounds include aziridine, pyridine, pyrimidine, pyrrolidine, piperidine, pyrazine, triazine, pyrrole, imidazole, indole, quinoline, isoquinoline, benzoisoquinoline, purine, pteridine, triazole, triazolidine, benzotriazole, carboxybenzotriazole, and derivatives having these frameworks. Among these, at least one selected from among benzotriazole and triazole is preferable. These nitrogen-containing heterocyclic compounds may be used alone or two or more thereof may be used in combination.

<Surfactant>

Examples of surfactants include anionic surfactants, cationic surfactants, and nonionic surfactants, but the present invention is not particularly limited thereto. Examples of anionic surfactants include sulfates such as alkyl ether sulfate and polyoxyethylene alkylphenyl ether sulfate; and fluorine-containing surfactants such as a perfluoroalkyl compound. Examples of cationic surfactants include aliphatic amine salts and aliphatic ammonium salts. Examples of nonionic surfactants include nonionic surfactants having triple bonds such as acetylene glycol, acetylene glycol ethylene oxide adduct, and acetylene alcohol; and polyethylene glycol type surfactants. These surfactants may be used alone or two or more thereof may be used in combination.

<Water-Soluble Polymer>

Examples of water-soluble polymers include polyacrylamide, polyvinyl alcohol, polyvinylpyrrolidone, polyethyleneimine, polyallylamine, and hydroxyethyl cellulose.

<Inorganic Acids and Salts Thereof>

The inorganic acid is preferably at least one selected from among hydrochloric acid, nitric acid, sulfuric acid, and phosphoric acid. Here, the inorganic acid may form a salt with a base that is separately added in the composition for chemical mechanical polishing.

<Basic Compound>

Examples of basic compounds include organic bases and inorganic bases. The organic base is preferably an amine, and examples thereof include triethylamine, monoethanolamine, benzylamine, methylamine, ethylenediamine, and diglycolamine, isopropylamine. Examples of inorganic bases include ammonia, potassium hydroxide, and sodium hydroxide. Among these basic compounds, ammonia and potassium hydroxide are preferable. These basic compounds may be used alone or two or more thereof may be used in combination.

1.6. pH

The pH of the composition for chemical mechanical polishing according to the present embodiment is preferably 1 or more and 6 or less, more preferably 2 or more and 6 or less, and particularly preferably 2.5 or more and 5.5 or less. When the pH is within the above range, since the absolute value of the zeta potential of the component (A) in the composition for chemical mechanical polishing is large and the dispersibility is improved, high-speed polishing can be performed while reducing the occurrence of polishing scratches and dishing on the semiconductor substrate including a tungsten film or a silicon nitride film.

Here, as necessary, the pH of the composition for chemical mechanical polishing according to the present embodiment can be adjusted by appropriately increasing or decreasing the content of the component (C), the inorganic acid and a salt thereof, the basic compound and the like.

In the present invention, the pH indicates a hydrogen ion index and the value thereof can be measured under conditions of 25° C. and 1 atm using a commercially available pH meter (for example, desktop pH meter commercially available from HORIBA, Ltd.).

1.7. Applications

The composition for chemical mechanical polishing according to the present embodiment is suitable as a polishing material for chemical mechanical polishing of a semiconductor substrate having a plurality of types of materials constituting a semiconductor device. For example, the semiconductor substrate may have, in addition to conductor metals such as tungsten and cobalt, insulating film materials such as silicon oxide, silicon nitride, and amorphous silicon, and barrier metal materials such as titanium, titanium nitride, and tantalum nitride.

An object to be polished of the composition for chemical mechanical polishing according to the present embodiment is particularly preferably a semiconductor substrate having a part containing at least a tungsten film and a silicon nitride film. Specific examples of such a semiconductor substrate include a semiconductor substrate in which a silicon nitride film is applied to a base of a tungsten film. According to the composition for chemical mechanical polishing of the present embodiment, it is possible to polish such a semiconductor substrate at a high speed and reduce the occurrence of surface defects on the polished surface after polishing.

1.8. Method of Preparing Composition for Chemical Mechanical Polishing

The composition for chemical mechanical polishing according to the present embodiment can be prepared by dissolving or dispersing the above components in a liquid medium such as water. The dissolving or dispersing method is not particularly limited, and any method may be applied as long as uniform dissolving or dispersion can be performed. In addition, the mixing order and mixing method of the above components are not particularly limited.

In addition, the composition for chemical mechanical polishing according to the present embodiment can be prepared as a concentrated type stock solution and used by being diluted in a liquid medium such as water during use.

### 2. Polishing Method

A polishing method according to one embodiment of the present invention includes a process in which a semiconductor substrate is polished using the above composition for chemical mechanical polishing. According to the above composition for chemical mechanical polishing, it is possible to polish a semiconductor substrate having a part containing a tungsten film or a silicon nitride film at a high speed and reduce the occurrence of polishing defects on the polished surface after polishing. The polishing method according to the present embodiment is particularly suitable when a semiconductor substrate in which a silicon nitride film is applied to a base of a tungsten film is polished. Hereinafter, one specific example of the polishing method according to the present embodiment will be described in detail with reference to the drawings.

2.1. Workpiece

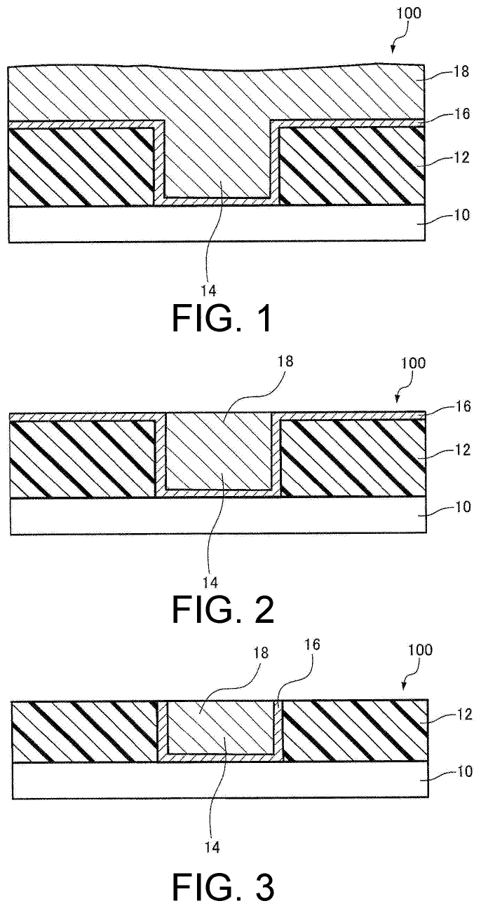

FIG. 1 is a cross-sectional view schematically showing a workpiece suitable for use in a polishing method according to the present embodiment. A workpiece 100 is formed through the following process (1) to process (4).

(1) First, as shown in FIG. 1, a substrate 10 is prepared. The substrate 10 may be composed of, for example, a silicon substrate and a silicon oxide film formed thereon. In addition, a functional device such as a transistor (not shown) may be formed on the substrate 10. Next, a silicon oxide film 12 which is an insulating film is formed on the substrate 10 using a thermal oxidation method.

(2) Next, the silicon oxide film 12 is patterned. A wiring groove 14 is formed in the silicon oxide film 12 by a photolithography method using the obtained pattern as a mask.

(3) Next, a silicon nitride film 16 is formed on the surface of the silicon oxide film 12 and the inner wall surface of the wiring groove 14. The silicon nitride film 16 can be formed by, for example, a chemical vapor deposition method (CVD), an atomic layer deposition method (ALD), or a physical vapor deposition method (PVD) such as sputtering.

(4) Next, a tungsten film 18 of 10,000 to 15,000 Å is deposited by the chemical vapor deposition method or the electroplating method. As the material of the tungsten film 18, not only high-purity tungsten but also an alloy containing tungsten can be used. The workpiece 100 can be produced through the above process (1) to process (4).

2.2. Polishing Method

2.2.1. First Polishing Process

FIG. 2 is a cross-sectional view schematically showing the workpiece 100 when a first polishing process ends. As shown in FIG. 2, the first polishing process is a process in which the tungsten film 18 is polished until the silicon nitride film 16 is exposed using a composition for chemical mechanical polishing which allows a tungsten film to be polished at a high speed.

2.2.2. Second Polishing Process

FIG. 3 is a cross-sectional view schematically showing the workpiece 100 when a second polishing process ends. As shown in FIG. 3, the second polishing process is a process in which the silicon nitride film 16 and the tungsten film 18 are polished until the silicon oxide film 12 is exposed using the above composition for chemical mechanical polishing (of the present invention). Since the above composition for chemical mechanical polishing (of the present invention) can minimize the polishing rate of the tungsten film in a well-balanced manner, it is possible to reduce the occurrence of dishing in a wiring part of the tungsten film, and polish the exposed tungsten film 18 and silicon nitride film 16 at a high speed and in a well-balanced manner. In addition, since the above composition for chemical mechanical polishing (of the present invention) has favorable dispersibility of the component (A), it is possible to reduce the occurrence of polishing scratches on the polished surface.

2.3. Chemical Mechanical Polishing Device

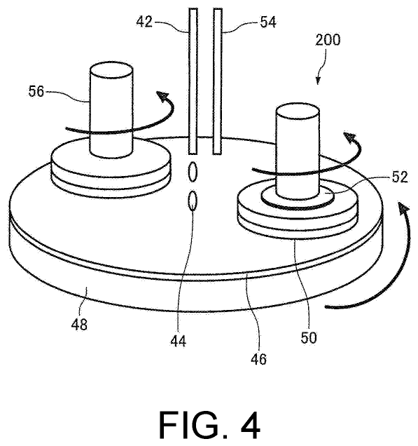

In the above first polishing process and second polishing process, for example, a polishing device 200 shown in FIG. 4 can be used. FIG. 4 is a perspective view schematically showing the polishing device 200. The above first polishing process and second polishing process are performed by supplying a slurry (composition for chemical mechanical polishing) 44 from a slurry supply nozzle 42, and bringing a carrier head 52 holding a semiconductor substrate 50 into contact with it while a turntable 48 to which a polishing cloth 46 is attached is rotated. Here, FIG. 4 also shows a water supply nozzle 54 and a dresser 56.

The polishing load of the carrier head 52 can be selected to be in a range of 0.7 to 70 psi, and is preferably 1.5 to 35 psi. In addition, the rotational speed of the turntable 48 and the carrier head 52 can be appropriately selected to be in a range of 10 to 400 rpm, and is preferably 30 to 150 rpm. The flow rate of the slurry (composition for chemical mechanical polishing) 44 supplied from the slurry supply nozzle 42 can be selected to be in a range of 10 to 1,000 mL/min, and is preferably 50 to 400 mL/min.

Examples of commercially available polishing devices include model “EPO-112” and “EPO-222” (commercially available from Ebara Corporation); model “LGP-510” and “LGP-552” (commercially available from Lap Master SFT); model “Mirra” and “Reflexion” (commercially available from Applied Materials, Inc.); model “POLI-400L” (commercially available from G&P TECHNOLOGY); and model “Reflexion LK” (commercially available from AMAT).

### 3. Examples

Hereinafter, the present invention will be described with reference to examples, but the present invention is not limited to these examples. Here, unless otherwise specified, “parts” and “%” in the present example are based on mass.

3.1. Preparation of Abrasive Grains

### <Preparation of Abrasive Grains A>

A titanyl sulfate solution was hydrolyzed by a general method, 40 kg of a 48% sodium hydroxide aqueous solution was added to 35 kg (10 kg in terms of TiO₂) of a hydrous titanium dioxide cake (titanium dioxide hydrate) that had been filtered and washed with stirring, and the mixture was then heated in a temperature range of 95 to 105° C. and stirred for 2 hours. Next, this slurry was filtered and washed sufficiently to obtain a base-treated titanium dioxide hydrate. Water was added to this hydrate cake to form a slurry, and the concentration in terms of TiO₂ was adjusted to 110 g/L. While stirring this slurry, 35% hydrochloric acid was added, and the pH was adjusted to 7.0.

Next, the slurry was heated to 50° C., 12.5 kg of 35% hydrochloric acid was added at this temperature for 4 minutes with stirring, and the hydrochloric acid concentration in the slurry after hydrochloric acid was added was adjusted to 40 g/L in terms of 100% HCl. The hydrochloric acid addition rate was 0.11 kg/min per 1 kg in terms of TiO₂. After hydrochloric acid was added, the slurry was heated and aged at 100° C. for 2 hours. Ammonia water was added to the slurry after aging and the pH was neutralized to 6.5. Then, filtering and washing with water were performed, dying was performed and crushing was then performed to obtain abrasive grains A.

<Preparation of Abrasive Grains B>

In a mixed solvent containing 100 g of pure water and 2,850 g of methanol, 300 g of the abrasive grains A were dispersed, and 50 g of 29% ammonia water was then added. 15.0 g of 3-mercaptopropyltrimethoxysilane was added to this dispersing liquid, and the mixture was refluxed at a boiling point for 6 hours. Then, pure water was added, and methanol and ammonia were replaced with water while maintaining the volume of the dispersing liquid. Addition of pure water was terminated when the pH of the dispersing liquid was 8.5 or less and the overhead temperature reached 100° C. After the dispersing liquid was left and the temperature was adjusted to 30° C. or lower, 30 g of a 35% hydrogen peroxide solution was added, and the mixture was additionally reacted for 6 hours while keeping the dispersing liquid at about 70° C. After the reaction was completed, the dispersing liquid was left and the temperature was adjusted to 30° C. or lower to obtain a dispersing liquid containing abrasive grains B in which the surface of the titanium oxide particles was modified with a sulfo group.

<Preparation of Abrasive Grains C>

In a mixed solvent containing 100 g of pure water and 2,850 g of methanol, 300 g of the abrasive grains A were dispersed, and 50 g of 29% ammonia water was then added. 40.0 g of 3-(triethoxysilyl)propyl succinic anhydride was added to this dispersing liquid, and the mixture was refluxed at a boiling point for 6 hours. Then, pure water was added, and methanol and ammonia were replaced with water while maintaining the volume of the dispersing liquid. Addition of pure water was terminated when the pH of the dispersing liquid was 8.5 or less and the overhead temperature reached 100° C. The dispersing liquid was left and the temperature was adjusted to 30° C. or lower to obtain a dispersing liquid containing abrasive grains C in which the surface of the titanium oxide particles was modified with a carboxyl group.

<Preparation of Abrasive Grains D>

1,000 g of the abrasive grains A were dispersed in a mixed solvent containing 100 g of pure water and 2,850 g of methanol, 5.0 g of 3-aminopropyltrimethoxysilane was then added, and the mixture was refluxed at a boiling point for 4 hours. Then, pure water was added and methanol was replaced with water while maintaining the volume of the dispersing liquid. Addition of pure water was terminated when the overhead temperature reached 100° C., the dispersing liquid was left, and the temperature was adjusted to 30° C. or lower to obtain a dispersing liquid containing abrasive grains D in which the surface of the titanium oxide particles was modified with an amino group.

<Preparation of Abrasive Grains E>

1,000 g of the abrasive grains A were dispersed in a mixed solvent containing 100 g of pure water and 2,850 g of methanol, 150.0 g of sodium silicate was then added, and the mixture was refluxed at a boiling point for 6 hours. Then, pure water was added and methanol was replaced with water while maintaining the volume of the dispersing liquid. Addition of pure water was terminated when the pH of the dispersing liquid was 8.5 or less and the overhead temperature reached 100° C., the dispersing liquid was left, and the temperature was adjusted to 30° C. or lower to obtain a dispersing liquid containing abrasive grains E in which the surface of the titanium oxide particles was coated with silica.

<Preparation of Abrasive Grains F>

1,000 g of the abrasive grains A were dispersed in a mixed solvent containing 100 g of pure water and 2,850 g of methanol, 50.0 g of sodium aluminate was then added, and the mixture was refluxed at a boiling point for 1 hour. Then, pure water was added and methanol was replaced with water while maintaining the volume of the dispersing liquid. Addition of pure water was terminated when the pH of the dispersing liquid was 8.5 or less and the overhead temperature reached 100° C., the dispersing liquid was left, and the temperature was adjusted to 30° C. or lower to obtain a dispersing liquid containing abrasive grains F in which the surface of the titanium oxide particles was coated with alumina.

<Preparation of Abrasive Grains G>

300 g of the abrasive grains E as a solid content were diluted with methanol to obtain a total weight of 900 g, and 50 g of pure water and 50 g of 29% ammonia water were then added. 5.0 g of 3-mercaptopropyltrimethoxysilane was added to this dispersing liquid, and the mixture was refluxed at a boiling point for 6 hours. Then, pure water was added, and methanol and ammonia were replaced with water while maintaining the volume of the dispersing liquid. Addition of pure water was terminated when the pH of the dispersing liquid was 8.5 or less and the overhead temperature reached 100° C. The dispersing liquid was left, the temperature was adjusted to 30° C. or lower, 10 g of 35% hydrogen peroxide solution was then added, and the mixture was additionally reacted for 6 hours while keeping the dispersing liquid at about 70° C. After the reaction was completed, the dispersing liquid was left and the temperature was adjusted to 30° C. or lower to obtain a dispersing liquid containing abrasive grains G in which the surface of the titanium oxide particles was modified with a sulfo group and coated with silica.

<Preparation of Abrasive Grains H>

300 g of the abrasive grains E as a solid content were diluted with methanol to obtain a total weight of 900 g, and 50 g of pure water and 50 g of 29% ammonia water were then added. 10.0 g of 3-(triethoxysilyl)propyl succinic anhydride was added to this dispersing liquid, and the mixture was refluxed at a boiling point for 6 hours. Then, pure water was added, and methanol and ammonia were replaced with water while maintaining the volume of the dispersing liquid. Addition of pure water was terminated when the pH of the dispersing liquid was 8.5 or less and the overhead temperature reached 100° C. The dispersing liquid was left and the temperature was adjusted to 30° C. or lower to obtain a dispersing liquid containing abrasive grains H in which the surface of the titanium oxide particles was modified with a carboxyl group and coated with silica.

<Preparation of Abrasive Grains I>

300 g of the abrasive grains E as a solid content were diluted with methanol to obtain a total weight of 950 g, 50 g of pure water and 2.0 g of 3-aminopropyltrimethoxysilane were then added, and the mixture was refluxed at a boiling point for 4 hours. Then, pure water was added and methanol was replaced with water while maintaining the volume of the dispersing liquid. Addition of pure water was terminated when the overhead temperature reached 100° C., the dispersing liquid was left, and the temperature was adjusted to 30° C. or lower to obtain a dispersing liquid containing abrasive grains I in which the surface of the titanium oxide particles was modified with an amino group and coated with silica.

<Preparation of Abrasive Grains J>

300 g of the abrasive grains F as a solid content were diluted with methanol to obtain a total weight of 900 g, and 50 g of pure water and 50 g of 29% ammonia water were then added. 5.0 g of 3-mercaptopropyltrimethoxysilane was added to this dispersing liquid, and the mixture was refluxed at a boiling point for 6 hours. Then, pure water was added, and methanol and ammonia were replaced with water while maintaining the volume of the dispersing liquid. Addition of pure water was terminated when the pH of the dispersing liquid was 8.5 or less and the overhead temperature reached 100° C. The dispersing liquid was left, the temperature was adjusted to 30° C. or lower, 10 g of 35% hydrogen peroxide solution was then added, and the mixture was additionally reacted for 6 hours while keeping the dispersing liquid at about 70° C. After the reaction was completed, the dispersing liquid was left and the temperature was adjusted to 30° C. or lower to obtain a dispersing liquid containing abrasive grains J in which the surface of the titanium oxide particles was modified with a sulfo group and coated with alumina.

<Preparation of Abrasive Grains K>

300 g of the abrasive grains F as a solid content were diluted with methanol to obtain a total weight of 900 g, and 50 g of pure water and 50 g of 29% ammonia water were then added. 10.0 g of 3-(triethoxysilyl)propyl succinic anhydride was added to this dispersing liquid, and the mixture was refluxed at a boiling point for 6 hours. Then, pure water was added, and methanol and ammonia were replaced with water while maintaining the volume of the dispersing liquid. Addition of pure water was terminated when the pH of the dispersing liquid was 8.5 or less and the overhead temperature reached 100° C. The dispersing liquid was left and the temperature was adjusted to 30° C. or lower to obtain a dispersing liquid containing abrasive grains K in which the surface of the titanium oxide particles was modified with a carboxyl group and coated with alumina.

<Preparation of Abrasive Grains L>

300 g of the abrasive grains F as a solid content were diluted with methanol to obtain a total weight of 950 g and 50 g of pure water and 2.0 g of 3-aminopropyltrimethoxysilane were then added, and the mixture was refluxed at a boiling point for 4 hours. Then, pure water was added and methanol was replaced with water while maintaining the volume of the dispersing liquid. Addition of pure water was terminated when the overhead temperature reached 100° C., the dispersing liquid was left, the temperature was adjusted to 30° C. or lower to obtain a dispersing liquid containing abrasive grains L in which the surface of the titanium oxide particles was modified with an amino group and coated with alumina.

3.2. Preparation of Composition for Chemical Mechanical Polishing

The abrasive grains shown in Table 1 to Table 3 were put into a polyethylene bottle having a volume of 1 L so that they had a predetermined mass %, organic acids (salts) and other additives were added so that the compositions shown in Table 1 to Table 3 were formed, and hydrogen peroxide (30% aqueous solution commercially available from Wako Pure Chemical Industries, Ltd.) as an oxidant was then added so that the compositions shown in Table 1 to Table 3 were formed, and additionally, the pH was adjusted to that shown in Table 1 to Table 3, pure water as a (B) liquid medium was added for adjustment so that a total amount of all components was 100 mass %, and thereby compositions for chemical mechanical polishing of examples and comparative examples were prepared. For the compositions for chemical mechanical polishing obtained in this manner, using a zeta potential measuring device (model “DT300” commercially available from Dispersion Technology Inc.), the zeta potential of the abrasive grains was measured, and the results are also shown in Table 1 to Table 3.

3.3. Evaluation Method

3.3.1. Evaluation of Polishing Rate

Using the composition for chemical mechanical polishing obtained above, a wafer having a 700 nm tungsten film with a diameter of 12 inches and a wafer having a 1,000 nm silicon nitride film with a diameter of 12 inches were used as workpieces, and the chemical mechanical polishing test was performed under the following polishing conditions for 60 seconds.

### <Polishing Conditions>

Polishing device: model “POLI-400L” commercially available from G&P TECHNOLOGY
Polishing pad: “multi-hard polyurethane pad; H800-type1(3-IS)775” commercially available from Fuji Boseki Kabushiki Kaisha Supply speed of composition for chemical mechanical polishing: 100 mL/min
Surface plate rotational speed: 100 rpm
Head rotational speed: 90 rpm
Head pressing pressure: 2 psi
Polishing rate (Å/min)=(film thickness before polishing-film thickness after polishing)/polishing time

Here, the thickness of the tungsten film was calculated by the following formula from the sheet resistance value and the volume resistivity of tungsten after measuring the resistance by a DC four-probe method with a resistivity measuring device (model “E-5” commercially available from NPS).

Film thickness (Å)=[volume resistivity (Ω·m) of tungsten film+sheet resistance value (Ω)]×10¹⁰

The thickness of the silicon nitride film was calculated by measuring a refractive index using a non-contact optical film thickness measuring device (model “NanoSpec 6100” commercially available from Nanometrics Japan).

Evaluation criteria for the polishing rate are as follows. The polishing rates of the tungsten film and the silicon nitride film, and evaluation results thereof are also shown in Table 1 to Table 3.

### (Evaluation Criteria)

“A” . . . When the polishing rate of either the tungsten film or the silicon nitride film was 300 Å/min or more, since a polishing time for a wiring having a tungsten film or a silicon nitride film could be significantly shortened in actual semiconductor polishing, it was determined to be good.
“B” . . . When the polishing rate of both the tungsten film and the silicon nitride film was lower than 300 Å/min, since the polishing rate was low and it was difficult to put into practical use, it was determined to be poor.

3.3.2. Evaluation of Flatness

As a workpiece, a test substrate in which a 12-inch wafer on which a 100 nm silicon nitride film was formed was processed into various patterns with a depth of 100 nm, a 10 nm TiN film was laminated, and a 200 nm tungsten film was then additionally laminated was used. This test substrate was polished under the following condition until the silicon nitride film was exposed. Using a needle-type profiling system (model “Dektak XTL” commercially available from BRUKER), in the polished surface after a polishing treatment, a step (dishing) of a tungsten/silicon oxide film wiring in a pattern part of tungsten wiring width (line, L)/silicon nitride film wiring width (space, S) of 0.18 μm/0.18 μm was confirmed.

### <Polishing Conditions>

Polishing device: commercially available from AMAT, model “Reflexion LK”
Polishing pad: “multi-hard polyurethane pad; H800-type1(3-1S)775” commercially available from Fuji Boseki Kabushiki Kaisha
Supply speed of composition for chemical mechanical polishing: 300 mL/min
Surface plate rotational speed: 100 rpm
Head rotational speed: 90 rpm
Head pressing pressure: 2.5 psi

Evaluation criteria for flatness evaluation are as follows. The amount of dishing and evaluation results thereof are also shown in Table 1 to Table 3.

### (Evaluation Criteria)

“A” . . . When the amount of dishing was less than 6.0 nm, the flatness was determined to be very good.
“B” . . . When the amount of dishing was 6.0 nm or more, the flatness was determined to be poor.

3.3.3. Defect Evaluation

A wafer having a silicon nitride film with a diameter of 12 inches, which is a workpiece was polished under the following condition for 1 minute.

### <Polishing Conditions>

Polishing device: model “Reflexion LK” commercially available from AMAT
Polishing pad: “multi-hard polyurethane pad; H800-type1(3-1S)775” commercially available from Fuji Boseki Kabushiki Kaisha
Supply speed of composition for chemical mechanical polishing: 300 mL/min
Surface plate rotational speed: 100 rpm
Head rotational speed: 90 rpm
Head pressing pressure: 2 psi

For the wafer having a silicon nitride film polished above, using a defect inspection device (model “Surfscan SP1” commercially available from KLA-Tencor), the total number of defects with a size of 90 nm or more was counted. Evaluation criteria are as follows. The total number of defects per wafer and evaluation results thereof are also shown in Table 1 to Table 3.

### (Evaluation Criteria)

“A” . . . When the total number of defects per wafer was less than 500, since it could be put into practical use, it was determined to be good.
“B” . . . When the total number of defects per wafer was 500 or more, since the yield of non-defective semiconductors deteriorated extremely, it could not be put into practical use, and it was determined to be poor.

3.4. Evaluation Results

Table 1 to Table 3 show compositions and evaluation results of compositions for chemical mechanical polishing of examples and comparative examples.

TABLE 1

| | | | Example | Example | Example | Example | Example |
|---|---|---|---|---|---|---|---|
| | | | 1 | 2 | 3 | 4 | 5 |
| Composition | Abrasive | Type | Abrasive | Abrasive | Abrasive | Abrasive | Abrasive |
| for chemical | grains | | grains B | grains C | grains D | grains G | grains I |
| mechanical | | Feature | Titanium | Titanium | Titanium | Titanium | Titanium |
| polishing | | | oxide + | oxide + | oxide + | oxide + | oxide + |
| | | | sulfo | carboxyl | amino group | silica + | silica + |
| | | | group | group | | sulfo | amino |
| | | | | | | group | group |
| | | Zeta potential | −32 | −12 | 29 | −31 | 22 |
| | | (mV) | | | | | |
| | | Zeta potential | 32 | 12 | 29 | 31 | 22 |
| | | absolute value | | | | | |
| | | Content (mass %) | 1.0 | 1.0 | 2.0 | 1.0 | 3.0 |
| | Organic | Type | Citric | Citric | Citric | | |
| | acids | | acid | acid | acid | | |
| | and salts | | | | | | |
| | thereof | Content (mass %) | 4 | 0.5 | 4 | | |
| | | Type | | | | | |
| | | Content (mass %) | | | | | |
| | Other | Type | | | | Phosphoric | Nitric |
| | additives | | | | | acid | acid |
| | | Content (mass %) | | | | 0.002 | 0.001 |
| | Oxidant | Content (mass %) | 1 | 1 | 2 | 1 | 2 |
| | pH | | 2.5 | 3.5 | 2.5 | 2.5 | 2.5 |
| Evaluation | Polishing | W polishing rate | 123 | 112 | 452 | 116 | 307 |
| item | rate | (Å/min) | | | | | |
| | | SiN polishing rate | 371 | 316 | 103 | 461 | 119 |
| | | (Å/min) | | | | | |
| | | Evaluation | A | A | A | A | A |
| | Flatness | Amount of dishing | 3.1 | 3.9 | 4.0 | 5.2 | 5.8 |
| | evaluation | (nm) | | | | | |
| | | Evaluation | A | A | A | A | A |
| | Defect | Number | 63 | 398 | 342 | 37 | 428 |
| | evaluation | Evaluation | A | A | A | A | A |

| | | | Example | Example | Example | Example |
|---|---|---|---|---|---|---|
| | | | 6 | 7 | 8 | 9 |
| Composition | Abrasive | Type | Abrasive | Abrasive | Abrasive | Abrasive |
| for chemical | grains | | grains K | grains J | grains B | grains L |
| mechanical | | Feature | Titanium | Titanium | Titanium | Titanium |
| polishing | | | oxide + | oxide + | oxide + | oxide + |
| | | | alumina + | alumina + | sulfo | alumina + |
| | | | carboxyl | sulfo | group | amine |
| | | | group | group | | |
| | | Zeta potential | −15 | −36 | −31 | −36 |
| | | (mV) | | | | |
| | | Zeta potential | 15 | 36 | 31 | 36 |
| | | absolute value | | | | |
| | | Content (mass %) | 3.0 | 1.0 | 1.0 | 1.0 |
| | Organic | Type | Alkylimino | Citric | Phthalic | Propionic |
| | acids | | dicarboxylic | acid | acid | acid |
| | and salts | | acid Na | | | |
| | thereof | Content (mass %) | 0.01 | 0.001 | 0.001 | 5 |
| | | Type | | | Polyacrylic | |
| | | | | | acid | |
| | | Content (mass %) | | | 0.01 | |
| | Other | Type | Sulfuric | | | |
| | additives | | acid | | | |
| | | Content (mass %) | 0.001 | | | |
| | Oxidant | Content (mass %) | 0.5 | 3 | 1 | 1 |
| | pH | | 5.5 | 4.0 | 4.0 | 2.5 |
| Evaluation | Polishing | W polishing rate | 241 | 137 | 120 | 118 |
| item | rate | (Å/min) | | | | |
| | | SiN polishing rate | 319 | 377 | 352 | 431 |
| | | (Å/min) | | | | |
| | | Evaluation | A | A | A | A |
| | Flatness | Amount of dishing | 3.1 | 2.9 | 4.1 | 2.4 |
| | evaluation | (nm) | | | | |
| | | Evaluation | A | A | A | A |
| | Defect | Number | 194 | 248 | 22 | 467 |
| | evaluation | Evaluation | A | A | A | A |

TABLE 2

| | | | Example | Example | Example | Example |
|---|---|---|---|---|---|---|
| | | | 10 | 11 | 12 | 13 |
| Composition | Abrasive | Type | Abrasive | Abrasive | Abrasive | Abrasive |
| for chemical | grains | | grains H | grains K | grains I | grains I |
| mechanical | | Feature | Titanium | Titanium | Titanium | Titanium |
| polishing | | | oxide + | oxide + | oxide + | oxide + |
| | | | silica+ | alumina + | silica + | silica + |
| | | | carboxyl | carboxyl | amino | amino |
| | | | group | group | group | group |
| | | Zeta potential | −20 | −18 | 25 | 19 |
| | | (mV) | | | | |
| | | Zeta potential | 20 | 18 | 25 | 19 |
| | | absolute value | | | | |
| | | Content (mass %) | 0.5 | 1.0 | 2.0 | 1.5 |
| | Organic | Type | Acetic | Oxalic | Propionic | Acetic |
| | acids and | | acid | acid | acid | acid |
| | salts | Content (mass %) | 0.003 | 0.7 | 1 | 0.001 |
| | thereof | Type | Dodecylbenzene | | | Dodecylaminoethyl- |
| | | | sulfonic | | | aminoethylglycine |
| | | | acid Na | | | |
| | | Content (mass %) | 0.02 | | | 0.005 |
| | Other | Type | | | | |
| | additives | | | | | |
| | | Content (mass %) | | | | |
| | Oxidant | Content (mass %) | 0.5 | 1 | 1 | 0.2 |
| | pH | | 4.5 | 3.5 | 3.0 | 5.5 |
| Evaluation | Polishing | W polishing rate | 112 | 125 | 458 | 436 |
| item | rate | (Å/min) | | | | |
| | | SiN polishing | 331 | 369 | 148 | 117 |
| | | rate (Å/min) | | | | |
| | | Evaluation | A | A | A | A |
| | Flatness | Amount of | 5.4 | 3.0 | 5.7 | 4.9 |
| | evaluation | dishing (nm) | | | | |
| | | Evaluation | A | A | A | A |
| | Defect | Number | 64 | 428 | 69 | 81 |
| | evaluation | Evaluation | A | A | A | A |

| | | | Example | Example | Example | Example |
|---|---|---|---|---|---|---|
| | | | 14 | 15 | 16 | 17 |
| Composition | Abrasive | Type | Abrasive | Abrasive | Abrasive | Abrasive |
| for chemical | grains | | grains B | grains D | grains G | grains K |
| mechanical | | Feature | Titanium | Titanium | Titanium | Titanium |
| polishing | | | oxide + | oxide + | oxide + | oxide + |
| | | | sulfo | amino | silica + | alumina + |
| | | | group | group | sulfo group | carboxyl |
| | | | | | | group |
| | | Zeta potential | −27 | 11 | −33 | −17 |
| | | (mV) | | | | |
| | | Zeta potential | 27 | 11 | 33 | 17 |
| | | absolute value | | | | |
| | | Content (mass %) | 1.0 | 2.0 | 1.0 | 1.0 |
| | Organic | Type | Citric | Citric | Citric | Citric |
| | acids and | | acid | acid | acid | acid |
| | salts | Content (mass %) | 1 | 4 | 0.0001 | 0.001 |
| | thereof | Type | | Glycine | Dodecylaminoethyl- | |
| | | | | | aminoethylglycine | |
| | | Content (mass %) | | 0.1 | 0.01 | |
| | Other | Type | Monoethanol | | | Polyethylene |
| | additives | | amine | | | glycol |
| | | Content (mass %) | 0.3 | | | 0.005 |
| | Oxidant | Content (mass %) | 1 | 1 | 0.3 | 1 |
| | pH | | 4.0 | 2.5 | 5.5 | 4.0 |
| Evaluation | Polishing | W polishing rate | 126 | 461 | 118 | 132 |
| item | rate | (Å/min) | | | | |
| | | SiN polishing | 347 | 104 | 302 | 349 |
| | | rate (Å/min) | | | | |
| | | Evaluation | A | A | A | A |
| | Flatness | Amount of | 3.5 | 4.0 | 5.9 | 3.1 |
| | evaluation | dishing (nm) | | | | |
| | | Evaluation | A | A | A | A |
| | Defect | Number | 352 | 91 | 454 | 42 |
| | evaluation | Evaluation | A | A | A | A |

TABLE 3

| | | | Comparative | Comparative | Comparative | Comparative |
|---|---|---|---|---|---|---|
| | | | Example 1 | Example 2 | Example 3 | Example 4 |
| Composition | Abrasive | Type | Abrasive | Abrasive | Abrasive | Silica A |
| for chemical | grains | | grains A | grains E | grains F | |
| mechanical | | Feature | Titanium oxide | Titanium | Titanium | Silica + |
| polishing | | | | oxide + | oxide + | sulfo |
| | | | | silica | alumina | group |
| | | Zeta potential | 7 | −2 | 6 | −32 |
| | | (mV) | | | | |
| | | Zeta potential | 7 | 2 | 6 | 32 |
| | | absolute value | | | | |
| | | Content (mass %) | 1.0 | 1.0 | 1.0 | 2.0 |
| | Organic | Type | | | Citric | Acetic |
| | acids and | | | | acid | acid |
| | salts | Content (mass %) | | | 0.00001 | 0.00003 |
| | thereof | Type | | | Dodecylbenzene | |
| | | | | | sulfonic acid Na | |
| | | Content (mass %) | | | 0.02 | |
| | Other | Type | Phosphoric | Sulfuric | | |
| | additives | | acid | acid | | |
| | | Content (mass %) | 0.00002 | 0.05 | | |
| | Oxidant | Content (mass %) | 1 | 1 | 2 | 1 |
| | pH | | 2.5 | 1.0 | 4.0 | 4.5 |
| Evaluation | Polishing | W polishing rate | 349 | 204 | 83 | 211 |
| item | rate | (Å/min) | | | | |
| | | SiN polishing | 251 | 175 | 152 | 519 |
| | | rate (Å/min) | | | | |
| | | Evaluation | A | B | B | A |
| | Flatness | Amount of | 5.9 | 7.6 | 5.4 | 11.4 |
| | evaluation | dishing (nm) | | | | |
| | | Evaluation | A | B | A | B |
| | Defect | Number | 2940 | 739 | 803 | 38 |
| | evaluation | Evaluation | B | B | B | A |

| | | | Comparative | Comparative | Comparative |
|---|---|---|---|---|---|
| | | | Example 5 | Example 6 | Example 7 |
| Composition | Abrasive | Type | Silica B | Alumina | Abrasive |
| for chemical | grains | | | | grains G |
| mechanical | | Feature | Silica | Alumina | Titanium |
| polishing | | | | | oxide + |
| | | | | | silica + |
| | | | | | sulfo group |
| | | Zeta potential | −4 | 26 | −7 |
| | | (mV) | | | |
| | | Zeta potential | 4 | 26 | 7 |
| | | absolute value | | | |
| | | Content (mass %) | 1.0 | 0.5 | 1.0 |
| | Organic | Type | Oxalic | Propionic | Dodecylaminoethyl- |
| | acids and | | acid | acid | aminoethylglycine |
| | salts | Content (mass %) | 0.007 | 0.01 | 0.05 |
| | thereof | Type | | | |
| | | Content (mass %) | | | |
| | Other | Type | | | |
| | additives | | | | |
| | | Content (mass %) | | | |
| | Oxidant | Content (mass %) | 2 | 0.5 | 0.2 |
| | pH | | 4.0 | 3.0 | 9.0 |
| Evaluation | Polishing | W polishing rate | 119 | 142 | 39 |
| item | rate | (Å/min) | | | |
| | | SiN polishing | 201 | 41 | 28 |
| | | rate (Å/min) | | | |
| | | Evaluation | B | B | B |
| | Flatness | Amount of | 10.4 | 8.3 | 11.1 |
| | evaluation | dishing (nm) | | | |
| | | Evaluation | B | B | B |
| | Defect | Number | 31 | 3009 | 794 |
| | evaluation | Evaluation | A | B | B |

For components in Table 1 to Table 3, the following products or reagents were used.

### <Abrasive Grains>

Abrasive grains A to abrasive grains L: the abrasive grains A to abrasive grains L produced above
Silica A: product name “PL-3D,” sulfo group-modified silica commercially available from Fuso Chemical Co., Ltd.
Silica B: product name “PL-3L,” unmodified silica commercially available from Fuso Chemical Co., Ltd.
Alumina: product name “Advanced Alumina Series AA-04” commercially available from Sumitomo Chemical Company, Ltd.

### <Organic Acids and Salts Thereof>

Citric acid: product name “purified citric acid (crystal) L” commercially available from Fuso Chemical Co., Ltd.
Phthalic acid: product name “phthalic acid” commercially available from FUJIFILM Wako Pure Chemical Corporation
Propionic acid: product name “Propionic Acid” commercially available from Tokyo Chemical Industry Co., Ltd.
Acetic acid: product name “acetic acid” commercially available from Kanto Chemical Co., Inc.
Oxalic acid: product name “oxalic acid” commercially available from FUJIFILM Wako Pure Chemical Corporation
Phthalic acid: product name “phthalic acid” commercially available from FUJIFILM Wako Pure Chemical Corporation
Glycine: product name “glycine” commercially available from Nippon Rika Co., Ltd.
Dodecylaminoethylaminoethylglycine: product name “Lebon S” (30% aqueous solution) commercially available from Sanyo Chemical Industries, Ltd.
Alkylimino dicarboxylic acid Na: product name “Pioneer C-158C” commercially available from Takemoto Oil & Fat Co., Ltd.
Dodecylbenzene sulfonic acid Na: product name “sodium dodecylbenzene sulfonate” commercially available from FUJIFILM Wako Pure Chemical Corporation
Polyacrylic acid: product name “Jurymer AC-10L,” weight average molecular weight (Mw)=50,000 commercially available from Toagosei Co., Ltd.

### <Inorganic Acid>

Nitric acid: product name “nitric acid 1.38” (60-61% aqueous solution) commercially available from Kanto Chemical Co., Inc.
Sulfuric acid: product name “high-purity sulfuric acid (96%)” (96% aqueous solution) commercially available from Kanto Chemical Co., Inc.
Phosphoric acid: product name “85% phosphoric acid” (85% aqueous solution) commercially available from Rasa Industries, Ltd.

### <Water-Soluble Polymer>

Polyethylene glycol: product name “PEG-20000-40W” (40% aqueous solution), weight average molecular weight (Mw)=20,000 commercially available from TOHO Chemical Industry Co., Ltd.

### <Basic Compound>

Monoethanolamine: product name “ethanolamine” commercially available from Hayashi Pure Chemical Ind., Ltd.

### <Oxidant>

Hydrogen peroxide: product name “hydrogen peroxide” (30% aqueous solution) commercially available from FUJIFILM Wako Pure Chemical Corporation

In Examples 1 to 17, it was found that, when the compositions for chemical mechanical polishing according to the present invention, which contained (A) abrasive grains containing titanium oxide and (B) a dispersion medium and having an absolute value of the zeta potential of the component (A) of 8 mV or higher, were used, good polishing characteristics could be obtained.

Comparative Examples 1 to 3 and 7 were examples in which a composition for chemical mechanical polishing containing (A) abrasive grains containing titanium oxide and having an absolute value of the zeta potential of the component (A) of lower than 8 mV was used. In this case, high-speed polishing and defect suppression could not be achieved in a well-balanced manner.

In Comparative Examples 4 to 6 in which (A) abrasive grains containing titanium oxide were not used, high-speed polishing and flatness could not be achieved in a well-balanced manner.

Based on the above results, it was found that, according to the composition for chemical mechanical polishing of the present invention, it was possible to polish a semiconductor substrate, particularly, a semiconductor substrate having a part containing at least one of a tungsten film and a silicon nitride film, at a high speed, and reduce the occurrence of surface defects on the polished surface after polishing.

The present invention is not limited to the above embodiments, and various modifications can be made. For example, the present invention includes any configurations that are substantially the same (for example, configurations with the same functions, methods and results, or configurations with the same purposes and effects) as the configurations described in the embodiments. In addition, the present invention includes configurations in which non-essential parts of the configurations described in the embodiments are replaced. In addition, the present invention includes configurations having the same operational effects as the configurations described in the embodiments or configurations that can achieve the same purposes. In addition, the present invention includes configurations in which a known technique is added to the configurations described in the embodiments.

### REFERENCE SIGNS LIST

10 Substrate
12 Silicon oxide film
14 Wiring groove
16 Silicon nitride film
18 Tungsten film
42 Slurry supply nozzle
44 Slurry (composition for chemical mechanical polishing)
46 Polishing cloth
48 Turntable
50 Semiconductor substrate
52 Carrier head
54 Water supply nozzle
56 Dresser
100 Workpiece
200 Polishing device

1. A composition for chemical mechanical polishing, comprising:
(A) abrasive grains containing titanium oxide; and
(B) a liquid medium,
wherein an absolute value of a zeta potential of the component (A) in the composition for chemical mechanical polishing is 8 mV or higher.

2. The composition for chemical mechanical polishing according to claim 1,
wherein the component (A) further contains an aluminum compound or a silicon compound.

3. The composition for chemical mechanical polishing according to claim 1,
wherein the component (A) has a functional group represented by the following General Formula (1):
—SO₃⁻M⁺ (1)
M⁺ represents a monovalent cation.

4. The composition for chemical mechanical polishing according to claim 3,
wherein the component (A) is abrasive grains having a surface to which the functional group represented by General Formula (1) is fixed via a covalent bond and containing titanium oxide.

5. The composition for chemical mechanical polishing according to claim 3,
wherein the zeta potential of the component (A) in the composition for chemical mechanical polishing is −10 mV or lower.

6. The composition for chemical mechanical polishing according to claim 1,
wherein the component (A) has a functional group represented by the following General Formula (2):
—COO⁻M⁺ (2)
M⁺ represents a monovalent cation.

7. The composition for chemical mechanical polishing according to claim 6,
wherein the component (A) is abrasive grains having a surface to which the functional group represented by General Formula (2) is fixed via a covalent bond and containing titanium oxide.

8. The composition for chemical mechanical polishing according to claim 6,
wherein the zeta potential of the component (A) in the composition for chemical mechanical polishing is −10 mV or lower.

9. The composition for chemical mechanical polishing according to claim 1,
wherein the component (A) has a functional group represented by the following General Formula (3) or the following General Formula (4):
—NR¹R² (3)
—N⁺R¹R²R³M⁻ (4)
in Formulae (3) and (4), R¹, R² and R³ each independently represent a hydrogen atom or a substituted or unsubstituted hydrocarbon group; and M⁻ represents an anion.

10. The composition for chemical mechanical polishing according to claim 9,
wherein the component (A) is abrasive grains having a surface to which the functional group represented by General Formula (3) or the General Formula (4) is fixed via a covalent bond and containing titanium oxide.

11. The composition for chemical mechanical polishing according to claim 9,
wherein the zeta potential of the component (A) in the composition for chemical mechanical polishing is +10 mV or higher.

12. The composition for chemical mechanical polishing according to claim 1,
wherein the pH is 1 or more and 6 or less.

13. The composition for chemical mechanical polishing according to claim 1,
wherein the content of the component (A) with respect to a total mass of the composition for chemical mechanical polishing is 0.1 mass % or more and 20 mass % or less.

14. The composition for chemical mechanical polishing according to claim 1, further comprising
(C) at least one selected from the group consisting of organic acids and salts thereof.

15. A polishing method, comprising
a process in which a semiconductor substrate is polished using the composition for chemical mechanical polishing according to claim 1.

16. The polishing method according to claim 15,
wherein the semiconductor substrate has a part containing at least one of a tungsten film and a silicon nitride film.

17. The composition for chemical mechanical polishing according to claim 2,
wherein the component (A) has a functional group represented by the following General Formula (1):
—SO₃⁻M⁺ (1)
M⁺ represents a monovalent cation.

18. The composition for chemical mechanical polishing according to claim 4,
wherein the zeta potential of the component (A) in the composition for chemical mechanical polishing is −10 mV or lower.

19. The composition for chemical mechanical polishing according to claim 2,
wherein the component (A) has a functional group represented by the following General Formula (2):
—COO⁻M⁺ (2)
M⁺ represents a monovalent cation.

20. The composition for chemical mechanical polishing according to claim 7,
wherein the zeta potential of the component (A) in the composition for chemical mechanical polishing is −10 mV or lower.
